(19) United States
(12) Patent Application Publication
(10) Pub. No.: US 2012/0229987 A1
(43) Pub. Date: Sep. 13, 2012

(54) ELECTRONIC APPARATUS WITH ELECTROMAGNETIC RADIATION SHIELDING

(75) Inventors: WEN-TANG PENG, Tu-Cheng (TW); GUANG-YI ZHANG, Shenzhen City (CN); WEI QIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/280,350

(22) Filed: Oct. 25, 2011

(30) Foreign Application Priority Data
Mar. 11, 2011 (CN) 201110058639.1

(51) Int. Cl. H05K 9/00

(52) U.S. Cl. 361/724

(57) ABSTRACT

An electronic apparatus includes a cabinet and a number of electronic devices mounted in the cabinet. The cabinet includes a bottom plate and a top plate. A top of each electronic device forms two flanges, and a bottom of each electronic device forms a number of first electromagnetic radiation shielding units. The top and bottom plates includes a number of second electromagnetic radiation shielding units for respectively resisting against the first shielding units and the flanges of the electronic elements adjacent to the top plate and bottom plate of the cabinet. The first electromagnetic radiation shielding units and the flanges of two neighboring electronic devices resist against each other.

### BACKGROUND

1. Technical Field

The present disclosure relates to an electronic apparatus able to prevent electromagnetic radiation leakage.

2. Description of Related Art

Generally speaking, electronic components such as servers in electronic equipment cabinets often generate electromagnetic radiation. Such electromagnetic radiation may be hazardous to human health.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of an electronic apparatus, the electronic apparatus includes a cabinet and an electronic device mounted in the cabinet.

FIG. 2 is an exploded, isometric view of FIG. 1.

FIG. 3 is an isometric, inverted view of the electronic device of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

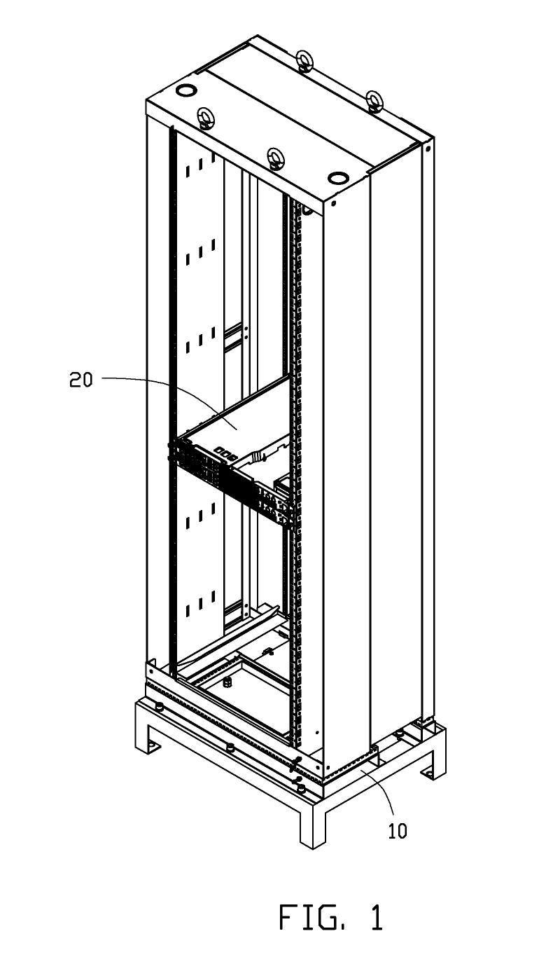

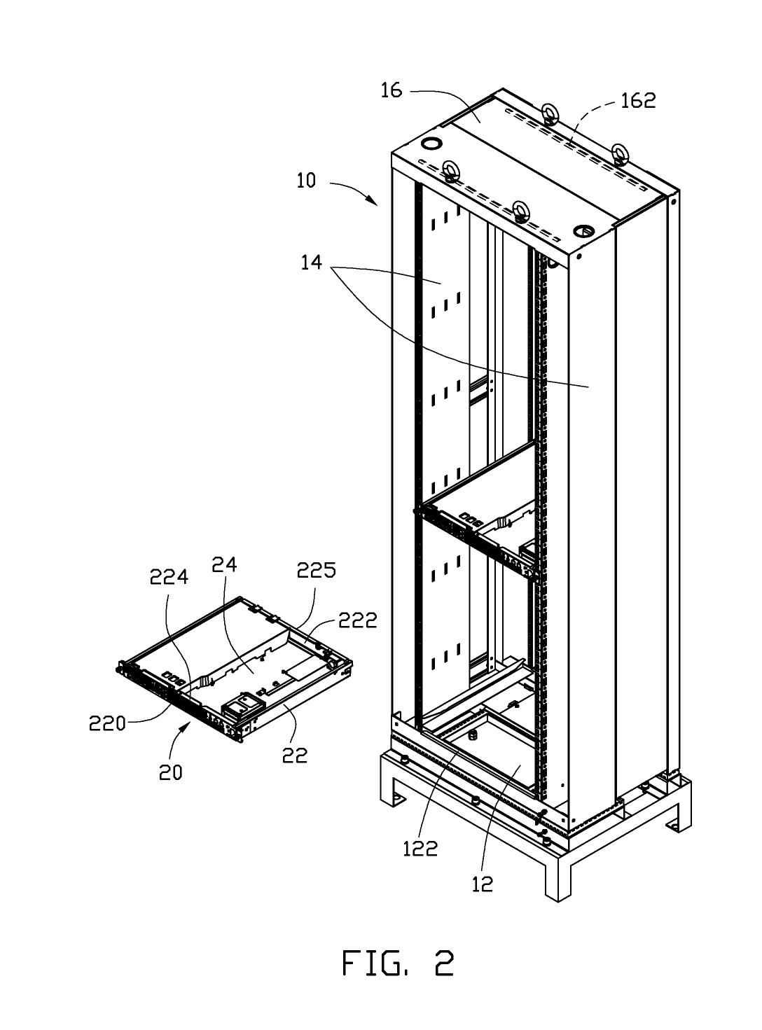

Referring to FIGS. 1 and 2, an exemplary embodiment of an electronic apparatus includes a cabinet 10 and a plurality of electronic devices 20 mounted in the cabinet 10. In this embodiment, the electronic apparatus is a rack-mount server system, the electronic devices 20 are server units, and only one of the electronic devices 20 is shown.

The cabinet 10 includes a bottom plate 12, two lateral plates 14 extending up in a substantially perpendicular manner from opposite sides of the bottom plate 12, and a top plate 16 connected between tops of the lateral plates 14. Two elongated bar shaped electromagnetic radiation shielding units 122 are installed to opposite sides of a top of the bottom plate 12. Two elongated bar shaped electromagnetic radiation shielding units 162 are installed to opposite sides of a bottom of the top plate 16. The electromagnetic radiation shielding units 122 and 166 are electromagnetic radiation shielding cloths, beryllium pieces, or copper pieces.

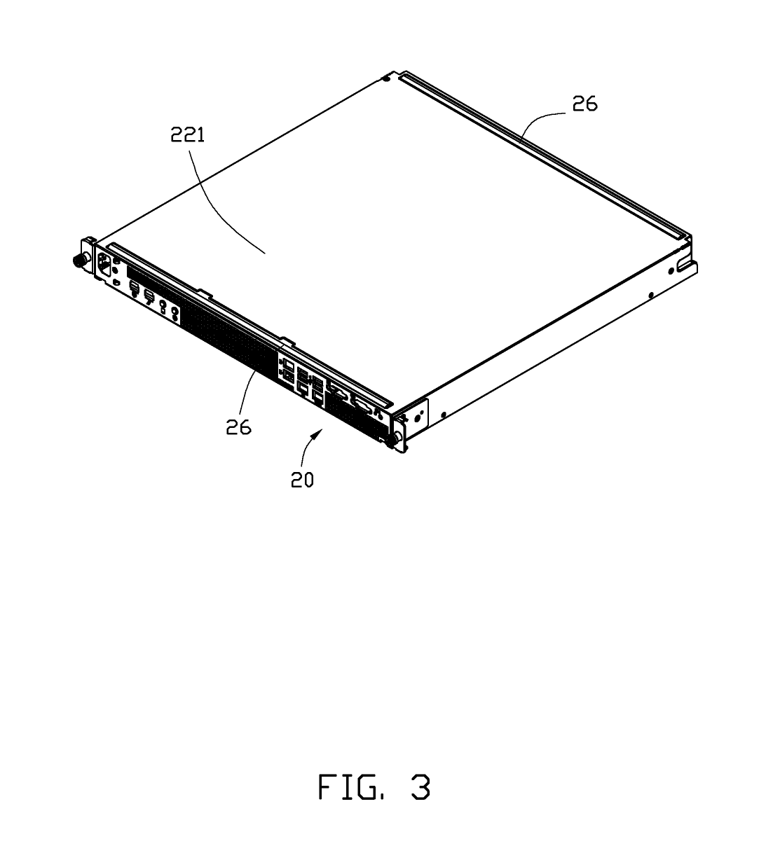

Referring to FIG. 3, each electronic device 20 includes a receiving body 22 with an opening, and a plurality of electronic components 24 received in the receiving body 22. The receiving body 22 includes a bottom wall 221, and two lateral walls 220 and 222 extending up in a substantially perpendicular manner from opposite sides of the bottom wall 221. A flange 224 extends in a substantially perpendicular manner from a top of the lateral wall 220 toward the lateral wall 222. A flange 225 extends in a substantially perpendicular manner from a top of the lateral wall 222 toward the lateral wall 220. Two elongated bar shaped electromagnetic radiation shielding units 26 are installed to the sides of the bottom wall 221, adjacent to the lateral walls 220 and 222, respectively. Each electromagnetic radiation shielding unit 26 is electromagnetic radiation shielding cloth, beryllium piece, or copper piece.

Referring to FIG. 1, the electronic devices 20 are mounted to the lateral plates 14 by slide rails (not shown). The electromagnetic radiation shielding units 26 of the upper electronic device 20 of two neighboring electronic devices 20 resist against the flanges 224 and 225 of the lower electronic device 20. The electromagnetic radiation shielding units 162 of the cabinet 10 resist against the flanges 224 and 225 of the electronic device 20 adjacent to the top of the cabinet 10. The electromagnetic radiation shielding units 122 of the cabinet 10 resist against the bottom wall 221 of the electronic device 20 adjacent to the bottom of the cabinet 10. Thereby, the electronic devices 20 and the cabinet 10 are connected together by the electromagnetic radiation shielding units 26, 162, and 122, and are connected to ground by the bottom plate 12 of the cabinet 10. The electromagnetic radiation shielding units 26, 162, and 122, and the cabinet 10 cover the gaps between two adjacent electronic devices 20 to prevent electromagnetic radiation leakage. Static electricity generated by the electronic components 24 of the electronic devices 20 is conducted to ground by the electromagnetic radiation shielding units 26, 162, and 122, and the bottom plate 12.

It is believed that the present embodiment and its advantages will be understood from the foregoing description, and it will be apparent that various changes may be made thereto without departing from the spirit and scope of the description or sacrificing all of their material advantages, the examples hereinbefore described merely being exemplary embodiments.

What is claimed is:

1. An electronic apparatus comprising:
a cabinet comprising a bottom plate, and a top plate opposite to the bottom plate; and
a plurality of electronic devices mounted in the cabinet, wherein a top of each of the electronic devices forms two flanges, and a bottom of each of the electronic devices forms a plurality of first electromagnetic radiation shielding units;
wherein the bottom plate comprises a plurality of second electromagnetic radiation shielding units resisting against the first electromagnetic radiation shielding units of the electronic device adjacent to the bottom plate; the top plate comprises a plurality of second electromagnetic radiation shielding units resisting against the flanges of the electronic device adjacent to the top plate, and the first electromagnetic radiation shielding units and the flanges of two neighboring electronic devices resist against each other.

2. The electronic apparatus of claim 1, wherein each electronic device comprises a receiving body, and a plurality of electronic components received in the receiving body.

3. The electronic apparatus of claim 2, wherein the receiving body comprises a bottom wall, and two lateral walls extending up from opposite sides of the bottom wall, the first electromagnetic radiation shielding units of the electronic device are installed at the bottom wall, the flanges extends in a substantially manner from tops of the lateral walls toward an inner side of the receiving body.

4. The electronic apparatus of claim 3, wherein the cabinet comprises two lateral plates extending up from opposite sides of the bottom plate, the electronic devices are mounted between the lateral plates.

5. The electronic apparatus of claim 4, wherein the top plate is connected between tops of the lateral plates, the second electromagnetic radiation shielding units of the top plate resist against the flanges of the electronic device adjacent to the top of the cabinet, the second electromagnetic radiation shielding units of the bottom plate resist against the bottom wall of the electronic device adjacent to the bottom of the cabinet.

6. The electronic apparatus of claim 1, wherein each electronic device comprises a receiving body, the receiving body comprises a bottom wall, and two lateral walls extending up from opposite sides of the bottom wall, the first electromagnetic radiation shielding units of the electronic device are installed to the bottom wall, the flanges extends in a substantially manner from tops of the lateral walls toward an inner side of the receiving body.

7. The electronic apparatus of claim 6, wherein the second electromagnetic radiation shielding units of the top plate resist against the flanges of the electronic device adjacent to the top of the cabinet, the second electromagnetic radiation shielding units of the bottom plate resist against the bottom wall of the electronic device adjacent to the bottom of the cabinet.

8. The electronic apparatus of claim 1, wherein each of the first and second electromagnetic radiation shielding units is electromagnetic radiation shielding cloth.

9. The electronic apparatus of claim 1, wherein each of the first and second electromagnetic radiation shielding units is a beryllium piece.

10. The electronic apparatus of claim 1, wherein each of the first and second electromagnetic radiation shielding units is a copper piece.

11. The electronic apparatus of claim 1, wherein the first and second electromagnetic radiation shielding units are both elongated bar shaped.
